(19) United States
(12) Patent Application Publication
(10) Pub. No.: US 2018/0337293 A1
(43) Pub. Date: Nov. 22, 2018

(54) PHOTOVOLTAIC DEVICES HAVING ROUGH METAL SURFACES

(71) Applicant: Alliance for Sustainable Energy, LLC, Golden, CO (US)

(72) Inventors: David Charles Bobela, Golden, CO (US); Marinus Franciscus Antonius Maria van Hest, Lakewood, CO (US); Scott Alan Mauger, Arvada, CO (US); James Bacon Whitaker, Denver, CO (US)

(21) Appl. No.: 15/977,008

(22) Filed: May 11, 2018

Related U.S. Application Data
(60) Provisional application No. 62/507,542, filed on May 17, 2017.

(51) Int. Cl. H01L 31/0236; H01L 31/0392; H01L 31/0725; H01L 31/18

(52) U.S. Cl. CPC H01L 31/02363; H01L 31/186; H01L 31/0725; H01L 31/0392

(57) ABSTRACT

The present disclosure relates to a device that includes, in order, a metal layer that includes aluminum, a first layer that includes a titanium oxide, a second layer that includes zinc oxide, and an absorber layer that includes indene-C60 bisadduct:poly(3-hexylthiophene) (ICBA:P3HT), where the metal layer has a thickness between one micrometer and 30 μm, and the metal layer has a roughness greater than 10 nm.

### CROSS-REFERENCE TO RELATED APPLICATIONS

This application claims the benefit of U.S. Provisional Patent Application No. 62/507,542 filed May 17, 2017, the contents of which are incorporated herein by reference in their entirety.

### CONTRACTUAL ORIGIN

The United States Government has rights in this invention under Contract No. DEAC36-08G028308 between the United States Department of Energy and Alliance for Sustainable Energy, LLC, the Manager and Operator of the National Renewable Energy Laboratory.

### BACKGROUND OF THE INVENTION

The present invention relates to thin film photovoltaic (PV) devices, which may be based on organic, inorganic, and/or hybrid materials. Related art thin film PV devices may be fabricated on thin, inexpensive, and flexible metal or plastic substrates such as stainless steel, polyethylene naphthalate (PEN) or polyethylene terephthalate (PET) and may be deposited by inexpensive and rapid roll-to-roll processing techniques. These advantages carve out unique niche applications for thin film PV devices.

Related art thin film PV devices may include a smooth metal surface that is formed on the substrate. However, it is expensive, time-consuming, and energy-intensive to deposit the smooth metal surface. In contrast, it would be advantageous to deposit a metal layer on the substrate or to use a metal layer as the bottom contact for the absorber layer, due to the low cost of the metal layer as compared to screen-printed or evaporated metals. However, the rough surface texture of the metal layer can degrade the performance of thin film PV devices, most notably by lowering the open circuit voltage.

### SUMMARY

An aspect of the present disclosure is a device that includes, in order, a metal layer that includes aluminum, a first layer that includes a titanium oxide, a second layer that includes zinc oxide, and an absorber layer that includes indene-C60 bisadduct:poly(3-hexylthiophene) (ICBA:P3HT), where the metal layer has a thickness between one micrometer and 30 μm, and the metal layer has a roughness greater than 10 nm.

In some embodiments of the present disclosure, the thickness may be between 10 μm and 20 μm. In some embodiments of the present disclosure, the roughness may be between 400 nm and 2 μm. In some embodiments of the present disclosure, the device may further include a substrate, where the metal layer is positioned between the first layer and the substrate. In some embodiments of the present disclosure, the substrate may include polyethylene naphthalate (PEN). In some embodiments of the present disclosure, the device may further include a third layer, where the absorber layer is positioned between the third layer and the second layer. In some embodiments of the present disclosure, the third layer may include poly(3,4-ethylenedioxythiophene) polystyrene sulfonate (PEDOT:PSS). In some embodiments of the present disclosure, the device may further include a fourth layer, where the third layer is positioned between the fourth layer and the absorber layer. In some embodiments of the present disclosure, the fourth layer may include indium zinc oxide.

An aspect of the present disclosure is a device that includes, in order, a metal layer that includes aluminum, a first layer that includes a titanium oxide, and an absorber layer that includes phenyl-C61-butyric acid methyl ester:poly(3-hexylthiophene) (PCBM:P3HT), where the metal layer has a thickness between one micrometer and 30 μm, and the metal layer has a roughness greater than 10 nm.

In some embodiments of the present disclosure, the thickness may be between 10 μm and 20 μm. In some embodiments of the present disclosure, the roughness may be between 400 nm and 2 μm. In some embodiments of the present disclosure, the device may further include a substrate, where the metal layer is positioned between the first layer and the substrate. In some embodiments of the present disclosure, the substrate may include polyethylene naphthalate (PEN). In some embodiments of the present disclosure, the device may further include a second layer, where the absorber layer is positioned between the first layer and the second layer. In some embodiments of the present disclosure, the second layer may include poly(3,4-ethylenedioxythiophene) polystyrene sulfonate (PEDOT:PSS). In some embodiments of the present disclosure, the device may further include a third layer, where the second layer is positioned between the third layer and the absorber layer. In some embodiments of the present disclosure, the third layer may include indium zinc oxide.

An aspect of the present disclosure is a method of fabricating a photovoltaic device, where the method includes depositing a first layer that includes at least one of titanium or a titanium oxide on a metal layer, where the metal layer has a roughness greater than 400 nm, depositing a second layer that includes zinc oxide on the first layer, and depositing an absorber layer on the second layer. An aspect of the present disclosure is a method of fabricating a photovoltaic device, where the method includes depositing a first layer that includes at least one of titanium or TiOₓ on a metal layer, where the metal foil has a roughness greater than 400 nm, and depositing a bulk heterojunction layer that includes an absorber layer on the first layer.

### BRIEF DESCRIPTION OF THE DRAWINGS

FIG. 1 shows the structure of a thin film PV device, according to some embodiments of the disclosure.

FIG. 2 shows the current density as a function of applied voltage for various organic photovoltaic (OPV) devices, according to some embodiments of the disclosure.

FIG. 3 shows the current density as a function of applied voltage for additional OPV devices, according to some embodiments of the disclosure.

### REFERENCE NUMERALS

| | |
|---|---|
| 100 | OPV device |
| 110 | substrate |
| 120 | metal layer |
| 130 | first layer |
| 140 | second layer |
| 150 | absorber layer |
| 160 | third layer |
| 170 | fourth layer |

### DETAILED DESCRIPTION

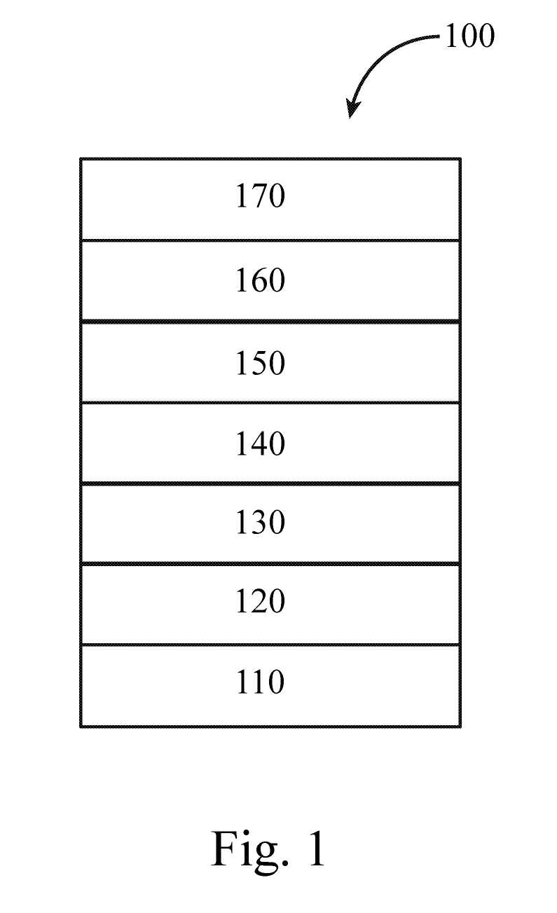

FIG. 1 shows a diagram of the structure of a thin film PV device, according to some embodiments of the present disclosure. The thicknesses of the layers shown in FIG. 1 are not drawn to scale. Although the layers are shown as being in direct contact with each other, additional materials or layers may be present between the layers that are shown in FIG. 1.

As shown in FIG. 1, the thin film PV device 100 may include a substrate 110 that is made of a flexible material. For example, the substrate 110 may be made of a polymer material, such as PEN or PET. A metal layer 120 (e.g. a metal foil) may be formed on the substrate 110. The metal layer 120 may be laminated to the substrate 110, and may be made of at least one of aluminum, silver, gold, molybdenum, and/or copper. The metal layer 120 may have any suitable thickness, such as 13 μm (0.5 mil), or between 1 μm and 30 μm. The surface of the metal layer 120 opposite to the substrate 110 may have a roughness that is greater than 400 nm, or between 400 nm and 2 μm. When compared to the roughness of metal layers deposited by vapor deposition methods, e.g. between 1 nm and 10 nm, or between 1 nm and 3 nm, aluminum foils according to some embodiments of the present disclosure, will have significantly higher roughness values (e.g. greater than 400 nm). In some embodiments of the present disclosure, a “rough” surface may be characterized as a surface having a roughness value greater than 10 nm, whereas a “smooth” surface may be characterized as a surface having a roughness value of less than or equal to 10 nm. As used herein, the term “roughness” is defined as the maximum difference in height between a peak and an adjacent valley on the surface of the metal layer 120. In an alternative embodiment, the thin film PV device may be formed without the substrate 110, such that the metal layer 120 is the bottom layer of the thin film PV device.

Some related art methods deposit a zinc oxide (ZnO) electron-selective layer on the metal layer 120 from a solution phase. In some embodiments of the present disclosure, other suitable conductive materials may be used, such as indium tin oxide. However, this solution phase deposition may not uniformly cover the rough surface of the metal layer 120, resulting in thinly coated or non-coated areas that act as shunt paths for current, thereby reducing the performance of the thin film PV device. It should also be noted that ZnO will not form on an aluminum surface, regardless of the roughness, from a precursor solution.

Accordingly, exemplary embodiments of the invention deposit a first layer 130 of titanium and/or titanium oxide (TiOₓ) onto a metal layer 120. For example, titanium may be deposited from the vapor phase at evaporation rates up to 2 Å/sec, and the resulting first layer 130 may have a thickness up to 25 nm. If exposed to atmosphere, the titanium may oxidize to form titanium dioxide (TiO₂) or another oxide (TiOₓ). Alternatively, TiOₓ may be deposited on a metal layer 120 by sputtering. As discussed in further detail below, the first layer 130 of titanium and/or TiOₓ allows a thin film PV device having the metal layer 120 with a rough surface to achieve high performance.

A second layer 140 of zinc oxide (ZnO) may then be deposited on the first layer 130. For example, ZnO may be spin-coated from a solution that includes Zn, such as diethylzinc (DEZ) and/or zinc acetate. The second layer 140 may have any suitable thickness, such as a dry thickness of approximately 50 nm.

As shown in FIG. 1, an absorber layer 150 may be deposited on the second layer 140. The absorber layer 150 may include an organic material, an inorganic material, and/or a perovskite material as an absorber material. For example, the absorber layer 150 may include phenyl-C61-butyric acid methyl ester:poly(3-hexylthiophene) (PCBM:P3HT) and/or indene-C60 bisadduct : poly(3-hexylthiophene) (ICBA:P3HT). In order to complete the PV device, a third layer 160 may then be deposited on the absorber layer 150. The third layer 160 may be made of a polymer material, such as poly(3,4-ethylenedioxythiophene) polystyrene sulfonate (PEDOT:PSS). Further, a fourth layer 170 may be deposited on the third layer 160. The fourth layer 170 may be made of a transparent conductor. For example, the fourth layer 170 may include nanowires, nanotubes, organic conductors, and/or a transparent conducting oxide (TCO), such as indium zinc oxide (IZO) or indium tin oxide (ITO).

Table 1 summarizes various devices that were constructed and tested, according to some embodiments of the present disclosure.

TABLE 1
Device Architectures

| | A | B | C | D | E | F |
|---|---|---|---|---|---|---|
| Fourth layer | IZO | IZO | IZO | IZO | IZO | IZO |
| (170) | | | | | | |
| Third layer | PEDOT: | PEDOT: | PEDOT: | PEDOT: | PEDOT: | PEDOT: |
| (160) | PSS | PSS | PSS | PSS | PSS | PSS |
| Absorber | PCBM: | PCBM: | PCBM: | ICBA: | ICBA: | ICBA: |
| (150) | P3HT | P3HT | P3HT | P3HT | P3HT | P3HT |
| Second layer | NA | NA | NA | NA | ZnO | ZnO |
| (140) | | | | | | |
| First layer | ZnO | TiOₓ | TiOₓ | TiOₓ | TiOₓ | TiOₓ |
| (130) | | | | | | |
| Metal layer | smooth | smooth | rough | smooth | smooth | rough |
| (120) | Al | Al | Al | Al | Al | Al |
| Metal layer | 0.150 | 0.150 | 13 | 0.150 | 0.150 | 13 |
| thickness | | | | | | |
| [μm] | | | | | | |
| Metal layer | <5 nm | <5 nm | >1 μm | <5 nm | <5 nm | >1 μm |
| roughness | | | | | | |
| Substrate | glass | glass | PEN | glass | glass | PEN |
| (110) | | | | | | |

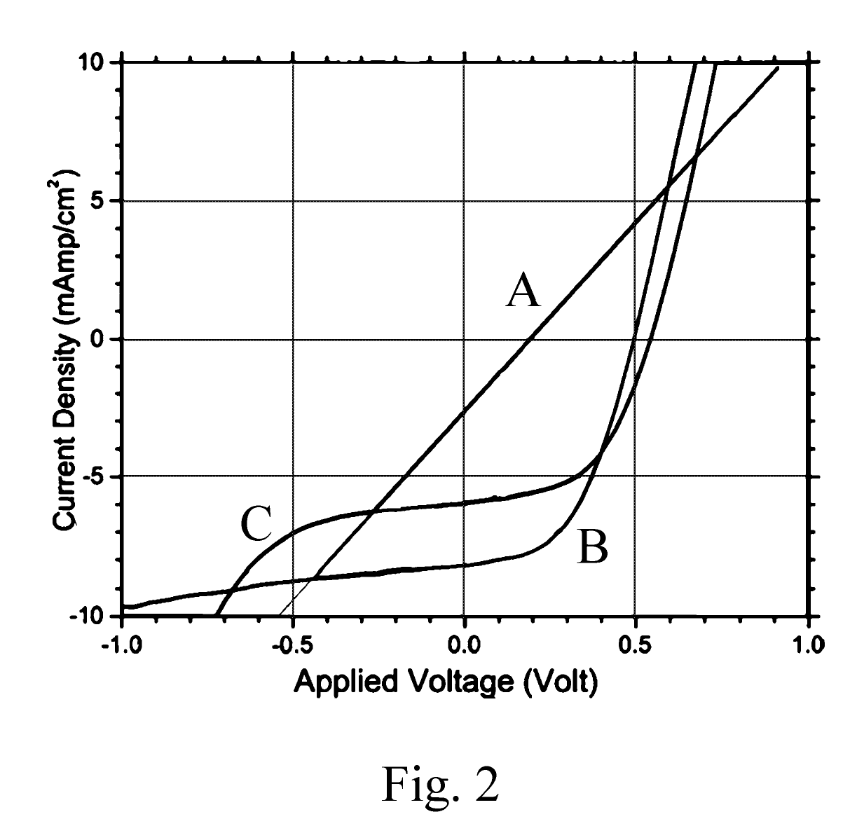

FIG. 2 shows the current density as a function of applied voltage for various OPV devices 100. As shown in FIG. 2, a first OPV device (B), which included a glass substrate, a smooth aluminum layer, a TiOₓ layer, a PCBM:P3HT layer, a PEDOT:PSS layer, and an IZO layer. The smooth aluminum layer in the first OPV device (B) was a thermally evaporated thin film. A second OPV device (A) included a glass substrate, a smooth aluminum layer, a ZnO layer, a PCBM:P3HT layer, a PEDOT:PSS layer, and an IZO layer. A third OPV device (C), according to some embodiments of the present disclosure, included a PEN substrate, a rough aluminum foil layer, a TiOₓ layer, a PCBM:P3HT layer, a PEDOT:PSS layer, and an IZO layer. Unexpectedly, despite the use of a rough aluminum metal layer (e.g. a metal foil), the performance of the third OPV device (C) was comparable to the performance of the first OPV device (B), which used a comparatively smooth aluminum metal layer. For example, OPV devices (C) and (B) have comparable fill factors and open-circuit voltages. Further, FIG. 2 shows that it is not necessary to include the ZnO layer to achieve a high-performance PV device with a rough aluminum foil and a PCBM-based bulk heterojunction layer.

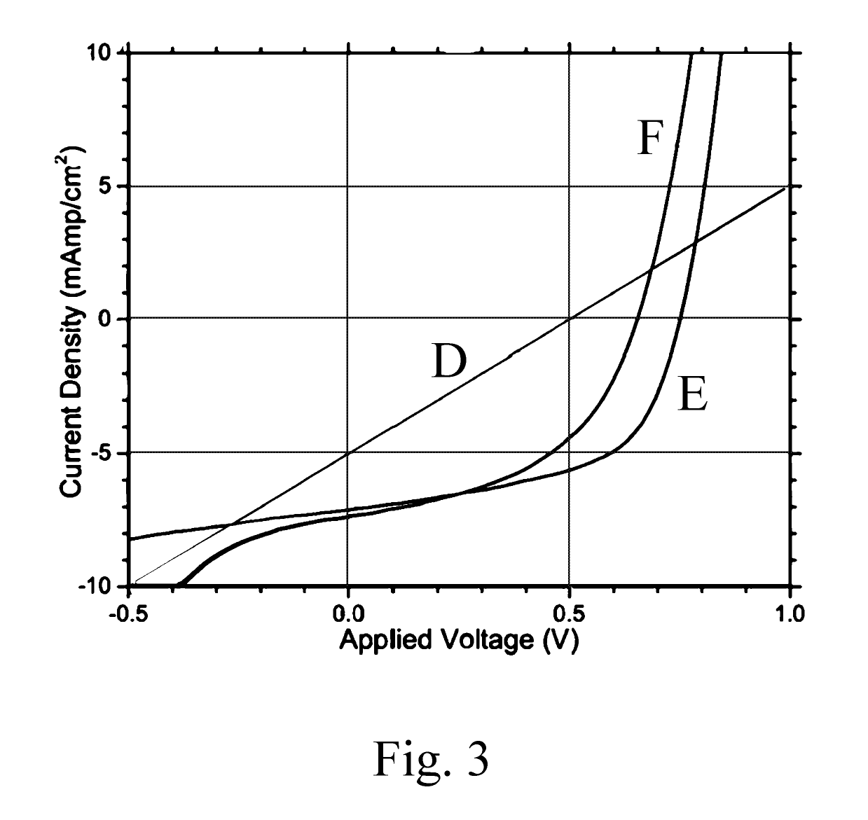

FIG. 3 shows the current density as a function of applied voltage for three additional OPV devices 100. As shown in FIG. 3, a fourth OPV device (E), which included a glass substrate, a smooth aluminum layer, a TiOₓ layer, a ZnO layer, an ICBA:P3HT layer, a PEDOT:PSS layer, and an IZO layer. A fifth OPV device (D) included a glass substrate, a smooth aluminum layer, a TiOₓ layer, an ICBA:P3HT layer, a PEDOT:PSS layer, and an IZO layer. A sixth OPV device (F), according to some embodiments of the present disclosure, included a PEN substrate, an aluminum foil layer, a TiOₓ layer, a ZnO layer, an ICBA:P3HT layer, a PEDOT:PSS layer, and an IZO layer. Unexpectedly, despite the use of a rough aluminum metal layer (e.g. a metal foil), the performance of the sixth OPV device (F) was comparable to the performance of the fourth related art OPV device, which used smooth aluminum layers.

As discussed above, the absorber layer 150 may include PCBM:P3HT and/or ICBA:P3HT. Due to the increased highest occupied molecular orbital (HOMO)—lowest unoccupied molecular orbital (LUMO) gap in the ICBA:P3HT material compared with the PCBM:P3HT material, using ICBA:P3HT may provide an increase in the open-circuit voltage of the OPV device. When using PCBM:P3HT as the absorber layer 150, the Ti/TiOₓ layer suffices to give nearly the full open-circuit voltage of approximately 580 mV. However, when using the ICBA:P3HT as the absorber layer 150, including the ZnO layer produces higher open-circuit voltages than the Ti/TiOₓ layer alone. This OPV device may achieve open-circuit voltages of at least 700 mV, such as 780 mV. FIG. 3 also shows that the ZnO layer should be included to achieve a high-performance PV device with a rough aluminum foil and an ICBA-based bulk heterojunction layer.

Without wishing to be bound by theory, FIG. 2 and FIG. 3 demonstrate that using ZnO directly on aluminum does not result in a functional device presumably due to the formation of a resistant Al₂O₃ layer between the ZnO and aluminum, causing the device performance to be poor (e.g. low FF). However, the titanium layer appears to eliminate and/or reduce the formation of this resistant Al₂O₃ layer. Although aluminum does typically have an oxide component, the addition of titanium to the aluminum may create an aluminum/Al₂O₃/titanium combination of layers. However, without wishing to be bound by the theory, the titanium may subsequently claim the oxygen from the Al₂O₃ resulting in a transformation of the titanium metal to a titanium oxide (TiOₓ) and an Al/TiOₓ/Ti combination of layers, which is a better conductor than Al₂O₃.

In addition, it appears that the energy levels of TiOₓ are not correct for ICBA based absorbers. However, the deposition of ZnO on the TiOₓ remedies this problem, resulting in a better performing device (see OPV devices (E) and (F) of FIG. 3). In the case of rough metals, where uniform coverage is a challenge, and where ICBA exposed directly to Al/Al₂O₃ performs poorly, the evaporation of titanium onto the aluminum prevent direct contact between the absorber and the ‘metal’. Some exposure by the absorber layer to the TiOₓ is fine as long as most of the absorber layer contacts ZnO, making the energy contacts. Hence, OPV devices (E) and (F) demonstrated very similar performances.

### EXPERIMENTAL

Smooth aluminum layers: deposited by thermal evaporation to a target thickness of about 150 nm. Evaporation rate was 2.0 Å/s. Deposition pressure was 1.8 e−7 torr.

TiOₓ layers: deposited titanium metal layers by thermal evaporation to a target thickness of about 10 nm. Evaporation rate was between 0.3 Å/S and 1.8 Å/S. Deposition pressure was 1.6 e⁻⁷ torr. Converted the titanium metal layers to TiOₓ layers by exposure to air for several hours.

P3HT:PCBM/ICBA layers: 1:1 wt in ortho-dichlorobenzene. 50 mg/mL total solids. Spin coated 60 μL at 700 rpm for 60 seconds in a N₂ glove box. A final thickness of about 250 nm was targeted for all OPV devices made.

PEDOT:PSS layers: spin coated in air. 350 μL at 4000 rpm for 60 seconds. Annealed at 150° C. for 5 minutes in N₂. Used Clevios HTL Solar version but could have used others with surfactants. A final thickness of about 50 nm was targeted.

ZnO layers: Solution was one part diethylzinc in toluene (15 wt %) to 3 parts tetrahydrofuran. Spin coated in air—250 μL at 7000 rpm for 30 s. Annealed in air at 120° C. for 20 minutes. A final thickness of about 40 nm was targeted.

### EXAMPLES

### Example 1

A device comprising, in order: a metal layer; a first layer comprising a titanium oxide; a second layer comprising zinc oxide; and an absorber layer.

### Example 2

The device of claim 1, wherein the metal layer comprises at least one of aluminum, silver, gold, molybdenum, or copper.

### Example 3

The device of claim 2, wherein the metal layer comprises aluminum.

### Example 4

The device of claim 1, wherein the metal layer has a thickness between one micrometer and 30 μm.

### Example 5

The device of claim 4, wherein the thickness is between 10 μm and 20 μm.

### Example 6

The device of claim 1, wherein the metal layer has a roughness of greater than 10 nm.

### Example 7

The device of claim 6, wherein the roughness is greater than 100 nm.

### Example 8

The device of claim 7, wherein the roughness is between 400 nm and 2 μm.

### Example 9

The device of claim 1, wherein the absorber layer comprises indene-C60 bisadduct:poly(3-hexylthiophene) (ICBA:P3HT).

### Example 10

The device of claim 1, further comprising a substrate, wherein the metal layer is positioned between the first layer and the substrate.

### Example 11

The device of claim 10, wherein the substrate comprises polyethylene naphthalate (PEN).

### Example 12

The device of claim 1, further comprising a third layer, wherein the absorber layer is positioned between the third layer and the second layer.

### Example 13

The device of claim 12, wherein the third layer comprises poly(3,4-ethylenedioxythiophene) polystyrene sulfonate (PEDOT:PSS).

### Example 14

The device of claim 12, further comprising a fourth layer, wherein the third layer is positioned between the fourth layer and the absorber layer.

### Example 15

The device of claim 14, wherein the fourth layer comprises indium zinc oxide.

### Example 16

The device of claim 1, wherein: the absorber layer comprises indene-C60 bisadduct:poly(3-hexylthiophene) (ICBA:P3HT), the metal layer comprises aluminum, the metal layer has a thickness between 10 μm and 20 μm, and the metal layer has a roughness between 400 nm and 2 μm.

### Example 17

A device comprising, in order: a metal layer; a first layer comprising a titanium oxide; and an absorber layer.

### Example 18

The device of claim 17, wherein the metal layer comprises at least one of aluminum, silver, gold, molybdenum, or copper.

### Example 19

The device of claim 18, wherein the metal layer comprises aluminum.

### Example 20

The device of claim 17, wherein the metal layer has a thickness between one micrometer and 30 μm.

### Example 21

The device of claim 20, wherein the thickness is between 10 μm and 20 μm.

### Example 22

The device of claim 17, wherein the metal layer has a roughness of greater than 10 nm.

### Example 23

The device of claim 22, wherein the roughness is greater than 100 nm.

### Example 24

The device of claim 23, wherein the roughness is between 400 nm and 2 μm.

### Example 25

The device of claim 17, wherein the absorber layer comprises phenyl-C61-butyric acid methyl ester:poly(3-hexylthiophene) (PCBM:P3HT).

### Example 26

The device of claim 17, further comprising a substrate, wherein the metal layer is positioned between the first layer and the substrate.

### Example 27

The device of claim 26, wherein the substrate comprises polyethylene naphthalate (PEN).

### Example 28

The device of claim 17, further comprising a second layer, wherein the absorber layer is positioned between the first layer and the second layer.

### Example 29

The device of claim 28, wherein the second layer comprises poly(3,4-ethylenedioxythiophene) polystyrene sulfonate (PEDOT:PSS).

### Example 30

The device of claim 28, further comprising a third layer, wherein the second layer is positioned between the third layer and the absorber layer.

### Example 31

The device of claim 30, wherein the third layer comprises indium zinc oxide.

### Example 32

The device of claim 17, wherein: the absorber layer comprises phenyl-C61-butyric acid methyl ester:poly(3-hexylthiophene) (PCBM:P3HT), the metal layer comprises aluminum, the metal layer has a thickness between 10 μm and 20 μm, and the metal layer has a roughness between 400 nm and 2 μm.

### Example 33

A method of fabricating a photovoltaic device, the method comprising: depositing a first layer comprising at least one of titanium or a titanium oxide on a metal layer, wherein the metal layer has a roughness greater than 400 nm; depositing a second layer comprising zinc oxide on the first layer; and depositing an absorber layer on the second layer.

### Example 34

The method of claim 33, wherein the first layer is deposited from a vapor phase.

### Example 35

The method of claim 33, wherein the second layer is spin-coated from a solution comprising Zn.

### Example 36

The method of claim 33, wherein the metal layer comprises aluminum.

### Example 37

The method of claim 33, wherein the absorber material comprises at least one of phenyl-C61-butyric acid methyl ester:poly(3-hexylthiophene) (PCBM:P3HT) or indene-C60 bisadduct:poly(3-hexylthiophene) (ICBA:P3HT).

### Example 38

The method of claim 37, wherein the absorber material comprises ICBA:P3HT.

### Example 39

The method of claim 33, further comprising: depositing a third layer comprising a polymer material on the bulk heterojunction layer; and depositing a fourth layer comprising a transparent conductor on the third layer.

### Example 40

A method of fabricating a photovoltaic device, the method comprising: depositing a first layer comprising at least one of titanium or TiOₓ on a metal layer, wherein the metal foil has a roughness greater than 400 nm; and depositing a bulk heterojunction layer comprising an absorber material on the first layer.

### Example 41

The method of claim 40, wherein the first layer is deposited from a vapor phase.

### Example 42

The method of claim 40, wherein the metal layer comprises aluminum.

### Example 43

The method of claim 40, wherein the absorber material comprises at least one of phenyl-C61-butyric acid methyl ester:poly(3-hexylthiophene) (PCBM:P3HT) or indene-C60 bisadduct:poly(3-hexylthiophene) (ICBA:P3HT).

### Example 44

The method of claim 40, further comprising: depositing a third layer comprising a polymer material on the bulk heterojunction layer; and depositing a fourth layer comprising a transparent conductor on the third layer.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A device comprising, in order:
a metal layer comprising aluminum;
a first layer comprising a titanium oxide;
a second layer comprising zinc oxide; and
an absorber layer comprising indene-C60 bisadduct:poly(3-hexylthiophene) (ICBA:P3HT), wherein:
the metal layer has a thickness between one micrometer and 30 μm, and
the metal layer has a roughness greater than 10 nm.

2. The device of claim 1, wherein the thickness is between 10 μm and 20 μm.

3. The device of claim 1, wherein the roughness is between 400 nm and 2 μm.

4. The device of claim 1, further comprising a substrate, wherein the metal layer is positioned between the first layer and the substrate.

5. The device of claim 4, wherein the substrate comprises polyethylene naphthalate (PEN).

6. The device of claim 1, further comprising a third layer, wherein the absorber layer is positioned between the third layer and the second layer.

7. The device of claim 6, wherein the third layer comprises poly(3,4-ethylenedioxythiophene) polystyrene sulfonate (PEDOT:PSS).

8. The device of claim 7, further comprising a fourth layer, wherein the third layer is positioned between the fourth layer and the absorber layer.

9. The device of claim 8, wherein the fourth layer comprises indium zinc oxide.

10. A device comprising, in order:
a metal layer comprising aluminum;
a first layer comprising a titanium oxide; and
an absorber layer comprising phenyl-C61-butyric acid methyl ester:poly(3-hexylthiophene) (PCBM:P3HT), wherein:
the metal layer has a thickness between one micrometer and 30 μm, and
the metal layer has a roughness greater than 10 nm.

11. The device of claim 10, wherein the thickness is between 10 μm and 20 μm.

12. The device of claim 10, wherein the roughness is between 400 nm and 2 μm.

13. The device of claim 10, further comprising a substrate, wherein the metal layer is positioned between the first layer and the substrate.

14. The device of claim 13, wherein the substrate comprises polyethylene naphthalate (PEN).

15. The device of claim 10, further comprising a second layer, wherein the absorber layer is positioned between the first layer and the second layer.

16. The device of claim 15, wherein the second layer comprises poly(3,4-ethylenedioxythiophene) polystyrene sulfonate (PEDOT:PSS).

17. The device of claim 15, further comprising a third layer, wherein the second layer is positioned between the third layer and the absorber layer.

18. The device of claim 17, wherein the third layer comprises indium zinc oxide.

19. A method of fabricating a photovoltaic device, the method comprising:
depositing a first layer comprising at least one of titanium or a titanium oxide on a metal layer, wherein the metal layer has a roughness greater than 400 nm;
depositing a second layer comprising zinc oxide on the first layer; and
depositing an absorber layer on the second layer.

20. A method of fabricating a photovoltaic device, the method comprising:
depositing a first layer comprising at least one of titanium or TiOₓ on a metal layer, wherein the metal foil has a roughness greater than 400 nm; and
depositing a bulk heterojunction layer comprising an absorber layer on the first layer.
